(19) United States
(12) Patent Application Publication
(10) Pub. No.: US 2013/0071505 A1
(43) Pub. Date: Mar. 21, 2013

(54) MOLDING DEVICE FOR SEMICONDUCTOR CHIP PACKAGE

(71) Applicant: JUN-YI XIAO, Zhongshan City (CN)

(72) Inventor: JUN-YI XIAO, Zhongshan City (CN)

(73) Assignees: HON HAI PRECISION INDUSTRY CO., LTD., Tu-Cheng (TW); Ambit Microsystems (Zhongshan) LTD., Zhongshan City (CN)

(21) Appl. No.: 13/293,124

(22) Filed: Nov. 10, 2011

(30) Foreign Application Priority Data
Sep. 21, 2011 (CN) 201110282255.8

(51) Int. Cl. H01L 21/56

(52) U.S. Cl. 425/116

(57) ABSTRACT

A molding device for a semiconductor chip package includes a first molding die, a second molding die opposite to the first molding die and a plurality of pistons. The second molding die defines a plurality of cylinders for receiving the corresponding pistons. The first molding die and the second molding die collectively form a molding cavity to accommodate a substrate. The first molding die includes a protruding portion defining a groove opening towards the second molding die. The protruding portion and the second molding die collectively form an entrance and an exit on two sides of the groove. Each of the plurality of pistons is compressed to force a molding compound flowing through the entrance, the groove and the exit to fill into the molding cavity so as to encapsulate the substrate.

### BACKGROUND

1. Technical Field

The present disclosure relates to molding devices, and more particularly to a molding device for a semiconductor chip package.

2. Description of Related Art

FIG. 8 illustrates a molding device 100 for a semiconductor chip package. The molding device 100 comprises a first molding die 110, a second molding die 120 opposite to the first molding die, a molding cavity 130 formed between the first molding die 110 and the second molding die 120, and a plurality of pistons 140. At least two substrates 200 are positioned on the second molding die 120 in the molding cavity 130. The second molding die 120 defines a plurality of cylinders 1200 for receiving the corresponding pistons 140. The substrates 200 are placed on two sides of the cylinders 1200 for supporting an array of semiconductor chips 300. The molding device 100 further defines a plurality of runners 150 between the first molding die 110 and the second molding die 120. Each of the plurality of runners 150 communicates the corresponding cylinder 1200 with the molding cavity 130, and each of the plurality of cylinders 1200 corresponds to the pair of runners 150. A molding compound 400 is forced out of the cylinders 1200 and passes through the runners 150 to enter the molding cavity 130 under pressure created by the pistons 140. When the molding compound 400 fills the molding cavity 130, the pistons 140 stand still for a predetermined time period until the molding compound 400 solidifies. Then, the pistons 140 are raised to open the first molding die 110, and a molded product is removed from the molding device 100. Extra parts, such as runners, are removed from the molded product, and the molded product is divided into individual units, whereby the semiconductor chip packages are completed.

Since the molding compound 400 is transferred into the molding cavity 130 along the runners 150 on the corner of the substrate 200, pressure of the molding compound 400 is distributed unevenly inside the molding cavity 130 during encapsulation, causing wire sweeping and molding defects, such as voids or holes. Further, since a flow path of the molding compound 400 within the cavity 130 is longer, a period of a molding cycle is prolonged and variations of a property of the molding compound 400 between different positions due to heating are enlarged thereby influencing the mold quality.

Therefore, a need exists in the industry to overcome the described limitations.

### BRIEF DESCRIPTION OF THE DRAWINGS

Many aspects of the present embodiments can be better understood with reference to the following drawings. The components in the drawings are not necessarily drawn to scale, the emphasis instead being placed upon clearly illustrating the principles of the present embodiments. Moreover, in the drawings, all the views are schematic, and like reference numerals designate corresponding parts throughout the several views.

FIG. 1 is a top view of one exemplary embodiment of a molding device in accordance with the present disclosure.

FIG. 2 is a cross-sectional view taken along line II-II of FIG. 1.

FIG. 3 is a sectional view enlarging a portion of a degating region and a portion of a substrate shown in FIG. 2.

FIG. 4 is a sectional view of the molding device in accordance with the present disclosure.

FIG. 5 is a partially enlarged sectional view of part V in FIG. 2.

FIG. 6 is a schematic cross-sectional view for illustrating the encapsulating process of chips mounted on the substrate installed in the molding device.

FIG. 7 is a schematic cross-sectional view for illustrating the substrate encapsulated by a molding compound.

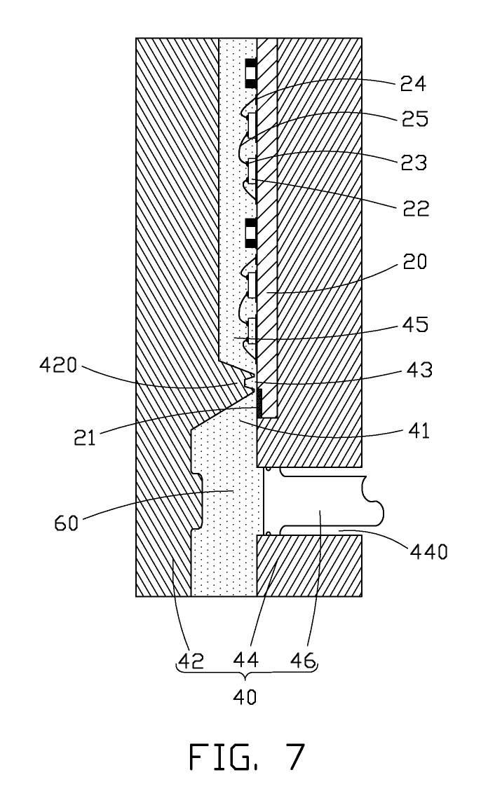

FIG. 8 is a schematic cross-sectional view of a conventional molding device.

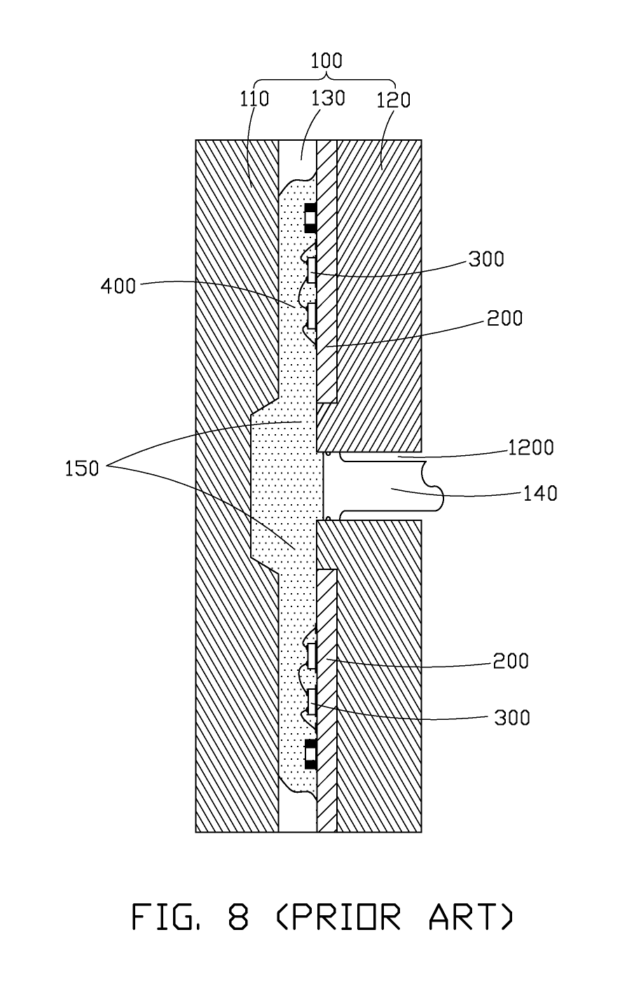

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean at least one.

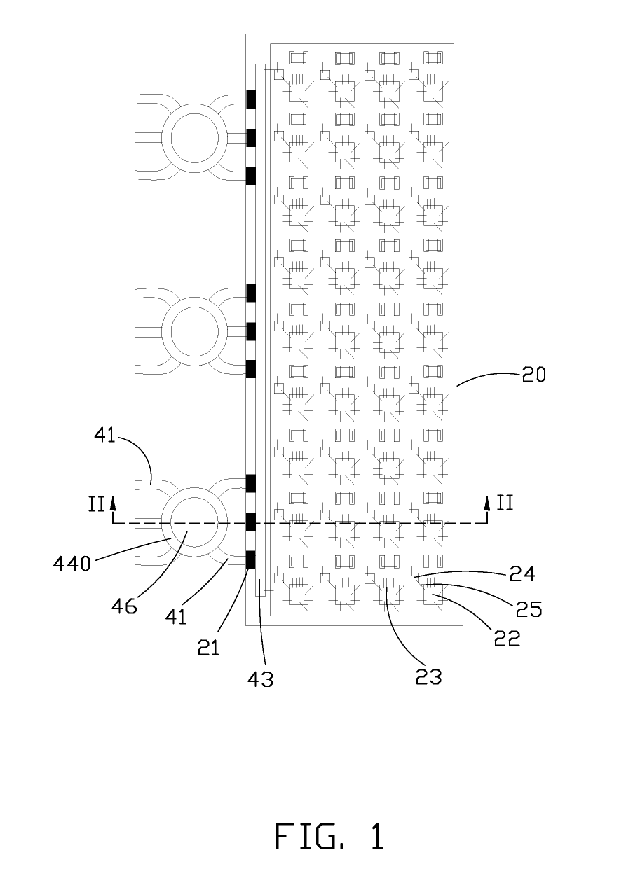

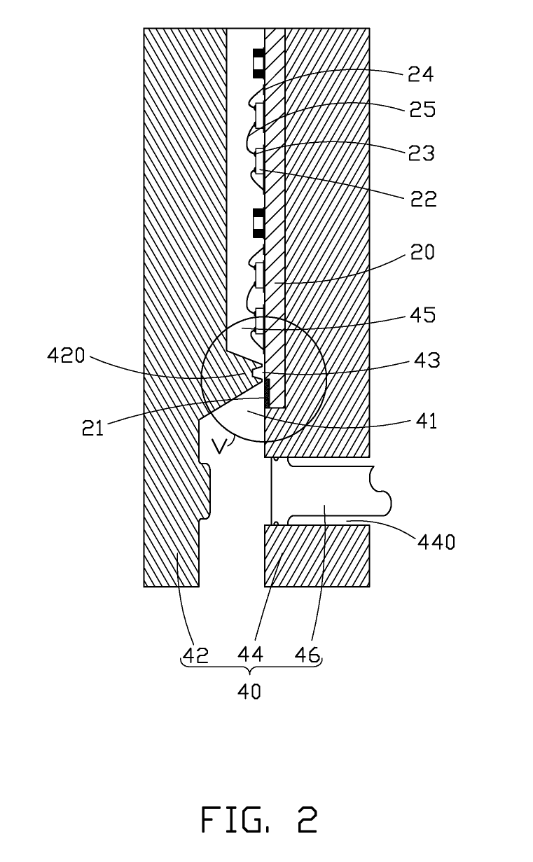

Referring to FIG. 1 and FIG. 2, a substrate 20 is used for encapsulation and is made of Flame-retardant epoxy-glass fabric composite resin (FR-4, RF-5) or Bismaleimide Triazine (BT). The substrate 20 comprises a plurality of semiconductor chips 22, a plurality of connecting portions 24, and a plurality of bonding wires 25. Each of the plurality of semiconductor chips 22 comprises a plurality of bonding pads 23, and each of the plurality of bonding wires 25 connects the corresponding bonding pad 23 to the connecting portion 24 to electrically connect the semiconductor chip 22 with the substrate 20.

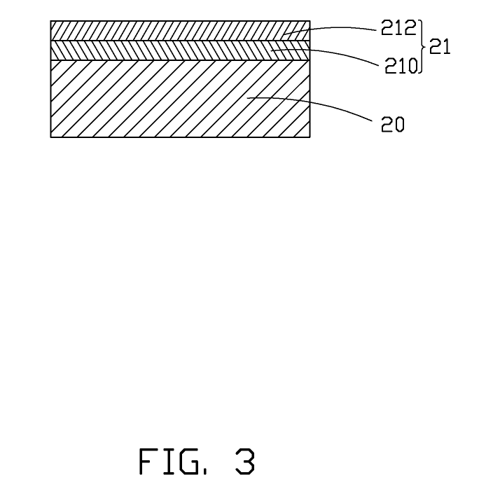

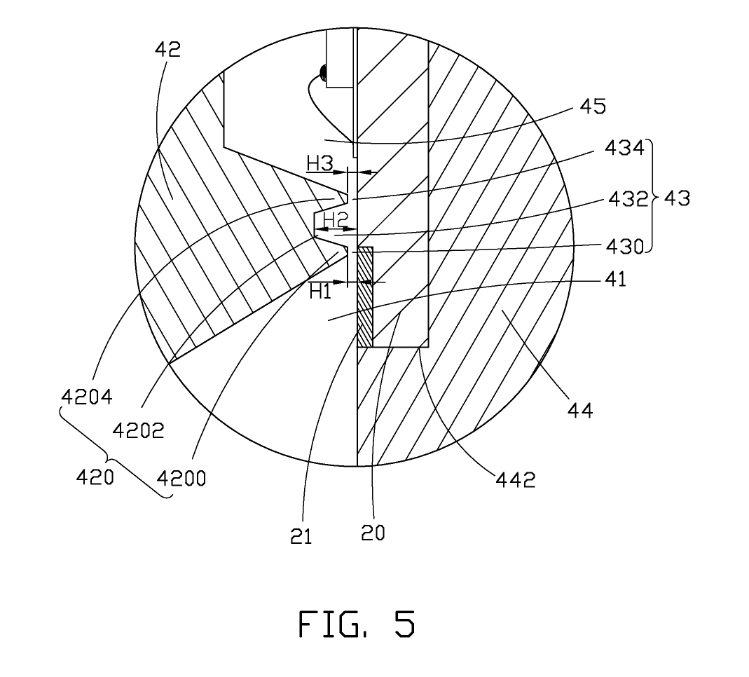

The substrate 20 comprises a degating region 21 structured on one side of the substrate 20. The degating region 21 comprises a first layer 210 and a second layer 212 as shown in FIG. 3. The first layer 210 can be made of copper, and the second layer 212 can be made of cuprum oxide or an organic protective film. In the other embodiment, the degating region 21 is structured as monolayer as shown in FIG. 5, and is made of, for example, copper, aurum or gold-nickel alloy.

In the illustrated embodiment, a molding device 40 is used to encapsulate a plurality of electronic elements, such as the semiconductor chips 22, on the substrate 20. The molding device 40 comprises a first molding die 42, a second molding die 44 opposite to the first molding die 42 and a plurality of pistons 46.

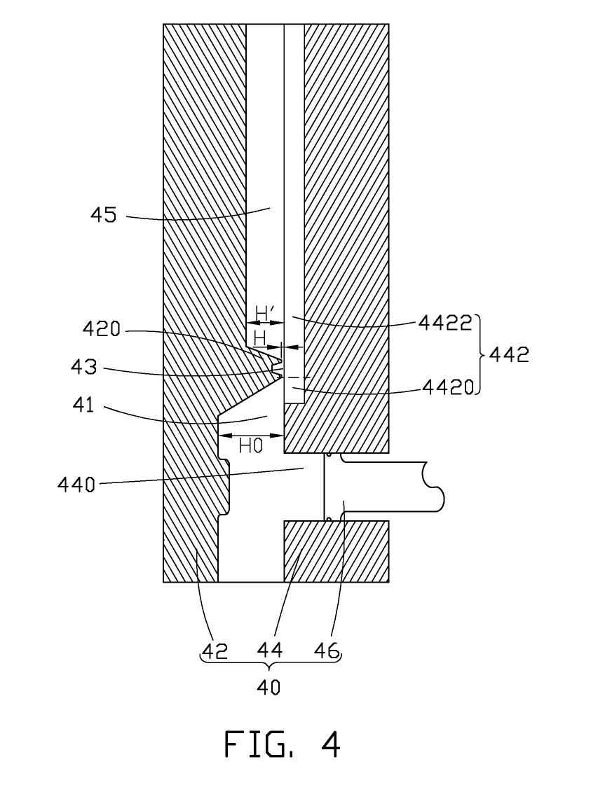

Referring to FIG. 4, the second molding die 44 defines a plurality of cylinders 440 and a recess portion 442. The plurality of cylinders 440 are configured on one side of the recess portion 442 to receive the corresponding piston 46. The recess portion 442 is opened towards the first molding die 42 for receiving the substrate 20, and comprises a first recess portion 4420 and a second recess portion 4422. In the embodiment, the first recess portion 4420 is configured between the plurality of cylinders 440 and communicates with the second recess portion 4422. In use, the substrate 20 is received in the recess portion 442, and more particularly the degating region 21 is received in the first recess portion 4420 and opposite to the first molding die 42.

The first molding die 42 comprises a protruding portion 420 protruding towards the recess portion 442 of the second molding die 44. In the illustrated embodiment, the protruding portion 420 is opposite to the second recess portion 4422 and contiguous with the first recess portion 4420; that is, the protruding portion 420 is opposite to the substrate 20 and contiguous with the degating region 21.

Referring to FIG. 5, the protruding portion 420 comprises a first block 4200 and a second block 4204. A groove 4202 is defined between the first block 4200 and the second block 4204 and is opposite to the recess portion 442. In the illustrated embodiment, the groove 4202 is configured towards one side of the second recess portion 4422 contiguous with the cylinders 440, and the first block 4200 is configured above the first recess portion 4420, that is, the groove 4202 is configured above one side of the degating region 21 away from the cylinders 440, and the first block 4200 is configured above the degating region 21.

In the illustrated embodiment, a cross section of the groove 4202 is shaped as a trapezoid as shown in FIG. 5. In other embodiments, the cross section of the groove 4202 can be shaped as a square, a triangle or an arc.

The molding device 40 defines a plurality of first runners 41, a second runner 43 and a molding cavity 45. The plurality of first runners 41 communicate with the corresponding cylinders 440 and extend from the corresponding cylinders 440 towards the first block 4200. In the illustrated embodiment, each of the cylinders 440 corresponds with a plurality of first runners 41, such as, two, four, or six first runners, and each of the first runners 41 corresponds with one degating region 21.

The second runner 43 is defined between the protruding portion 420 and the second molding die 44, and communicates with the plurality of first runners 41 and the molding cavity 45. The second runner 43 includes an entrance 430, a receiving cavity 432, and an exit 434. The entrance 430 is defined between the first block 4200 and the second molding die 44 and communicates with the first runners 41 and the receiving cavity 432, the receiving cavity 432 is defined between the groove 4204 and the second molding die 44 and communicates with the entrance 430 and the exit 434, and the exit 434 is defined between the second block 4204 and the second molding die 44 and communicates with the receiving cavity 432 and the molding cavity 45.

In the illustrated embodiment, a height H1 of the entrance 430 is substantially equal to a height H3 of the exit 434, and less than a height H2 of the receiving cavity 432, that is, H1=H3<H2, as shown in FIG. 5.

The molding cavity 45 communicating with the recess portion 442 is formed between the first molding die 42 and the second molding die 44 and configured at one side of the second block 4204 away from the second runner 43. That is, the substrate 20 is received in the recess portion 442 and partially received in the molding cavity 45.

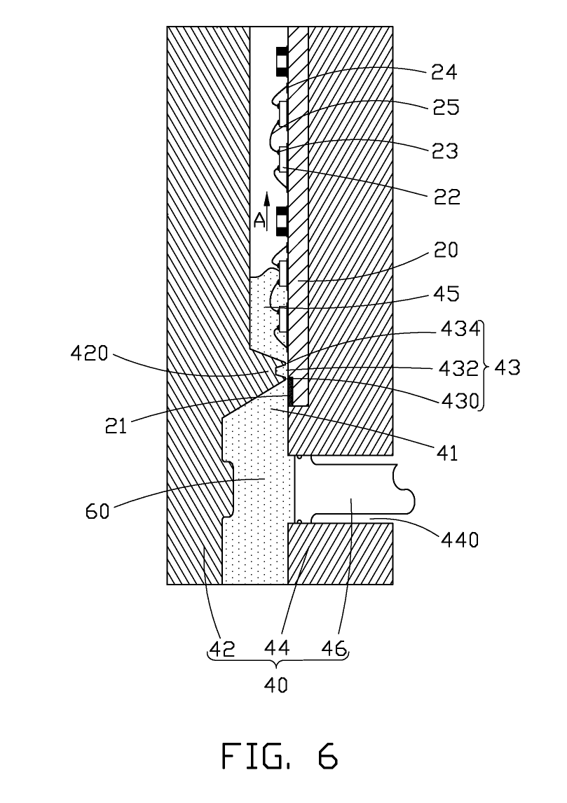

Referring to FIG. 6, a molding compound 60 flows through the plurality of first runners 41 and the second runners 43 in turn, and is eventually filled into the molding cavity 45 to encapsulate the semiconductor chips 22 on the substrate 20. Since the protruding portion 420 is configured between the plurality of first runners 41 and the molding cavity 45 and protrudes from the first molding die 42 towards the second molding die 44, a height H of the second runner 43 is less than a height H0 of the first runner 41 or a height H′ of the molding cavity 45 to decrease a flowing speed of the molding compound 60, that is, H<H′ or H<H0, as shown in FIG. 4.

In detail, the molding compound 60 first flows through the plurality of first runners 41 into the entrance 430, where the flowing speed of the molding compound 60 is limited and slowed by the first block 4200 so as to prevent bubble generation or holes. Subsequently, the molding compound 60 flows into the receiving cavity 432. Due to the height H of the receiving cavity 432 being greater than the height H1 of the entrance 430, the receiving cavity 432 would steady the flowing speed of the molding compound 60. The molding compound 60 flows from the receiving cavity 432 through the exit 434 to the molding cavity 45, and the molding compound 60 is retarded by the second block 4204 and the flowing speed of the molding compound 60 is further reduced.

Since the flowing speed of the molding compound 60 is reduced, the plurality of bonding wires 25 are prevented from being broken by the molding compound 60. In addition, the groove 4202 is contiguous to the degating region 21 to decrease an area of the degating region 21 so as to reduce production cost of the semiconductor chip package.

After the first molding die 42 is engaged and clamped with the second molding die 44, the plurality of pistons 46 are compressed to force the molding compound 60 passing through the corresponding cylinders 440 and filling the corresponding first runner 41. Then the molding compound 60 flows through the first runners 41, passes through the entrance 430, the receiving cavity 432 and the exit 434 in turn, and eventually fills the molding cavity 45 along a moving direction A to encapsulate the plurality of semiconductor chips 22 on the substrate 20, as shown in FIG. 6. In the illustrated embodiment, each of the plurality of bonding pads 23 is perpendicular to the moving direction A of the molding compound 60 and the bonding wires 25 are parallel with the moving direction A to prevent the molding compound 60 breaking the bonding wires 25.

When the molding compound 60 fills the molding cavity 45, the pistons 46 stand still for a predetermined time until the molding compound 60 solidifies. Then the pistons 46 are raised to open the first molding die 42, and a molded product is removed from the molding device 40. Extra parts, such as molding compound 60 solidified in the first runners 41, are removed from the molded product, and the molded product is sawed into individual units, whereby the semiconductor chip packages are completed.

The present disclosure discloses that the second runner 43 of the molding device 40 defines the receiving cavity 432 communicating with the first runners 41 and the molding cavity 45 to keep a pressure in the first runners 41 stay in the same level. Therefore, the molding compound 60 evenly fills into the molding cavity 45 along the second runner 43 when compressing the pistons 46.

The present disclosure also discloses that the degating region 21 is configured in the first runner 41 and contiguous with the second runner 43 to control the molding compound 60 flow stably and to reduce a period of encapsulation, and the molding compound 60 formed within the degating region 21 can be easily peeled off since the adhesion between the package product and the degation region 21 is less than that between the substrate 20 and the package product.

The present disclosure further discloses that the degation region 21 in one end of the substrate 20 is received in the first recess portion 4420 to enhance a rigidity of the substrate 20 located in the first runner 41, hence the substrate 20 will be prevented from bending under the pressed and heated condition and the molding compound 60 will be avoided filling in bottom of the substrate 20.

Although the features and elements of the present disclosure are described as embodiments in particular combinations, each feature or element can be used alone or in other various combinations within the principles of the present disclosure to the full extent indicated by the broad general meaning of the terms in which the appended claims are expressed.

1. A molding device for a semiconductor chip package, comprising a first molding die, a second molding die opposite to the first molding die and a plurality of pistons, the second molding die defining a plurality of cylinders for receiving the corresponding pistons, the first molding die and the second molding die collectively forming a molding cavity to accommodate a substrate, the first molding die comprising a protruding portion protruding towards the second molding die in the molding cavity, the protruding portion defining a groove opening towards the second molding die, and collectively forming an entrance and an exit on two sides of the groove with the second molding die, each of the plurality of pistons compressed to force a molding compound flowing through the entrance, the groove and the exit to fill into the molding cavity so as to encapsulate the substrate.

2. The molding device as claimed in claim 1, wherein a cross section of the groove is shaped as a trapezoid.

3. The molding device as claimed in claim 1, wherein a cross section of the groove is selectively shaped as a square, a triangle and an arc.

4. The molding device as claimed in claim 1, wherein the molding device defines a plurality of first runners extending from the corresponding cylinders towards the protruding portion, each of the plurality of first runners communicates with the corresponding cylinder and the entrance.

5. The molding device as claimed in claim 4, wherein the protruding portion comprises a first block and a second block, the groove is defined between the first block and the second block, the entrance is defined between the first block and the second molding die, a receiving cavity is defined between the groove and the second molding die to communicate with the entrance and the exit, and the exit is defined between the second block and the second molding die and communicates with the receiving cavity and the molding cavity.

6. The molding device as claimed in claim 5, wherein a height of the entrance is substantially equal to that of the exit, and is less than that of the receiving cavity.

7. The molding device as claimed in claim 1, wherein the second molding die further defines a first recess portion and a second recess portion communicating with the first recess portion to collectively receive the substrate, the first recess portion is configured between the plurality of cylinders, the first recess portion and the second recess portion communicate with the molding cavity and open towards the first molding die.

8. The molding device as claimed in claim 7, wherein the substrate comprises a degating region structured on one side of the substrate, the substrate is received in the first recess portion and the degating region is received in the first recess portion and opposite to the first molding die.

9. The molding device as claimed in claim 8, wherein the degating region comprises a first layer and a second layer, the first layer is made of copper and the second layer is selectively made of cuprum oxide and an organic protective film.

10. The molding device as claimed in claim 8, wherein the degating region is structured as monolayer and made of copper, aurum or gold-nickel alloy.

11. A molding device, used to encapsulate a plurality of electronic elements on a substrate, comprising a first molding die and a second molding die opposite with each other and collectively forming a molding cavity, the substrate fixed on the second molding die and received in the molding cavity, a plurality of first runners and a second runner configured between and communicating with the plurality of first runners and the molding cavity, the second runner defining an entrance, a receiving cavity and an exit, wherein a molding compound is configured to flow through the plurality of first runners, the entrance, the receiving cavity, and the exit in turn, and fill the molding cavity so as to encapsulate the plurality of electronic elements on the substrate.

12. The molding device as claimed in claim 11, wherein a protruding portion protrudes towards the second molding die, the protruding portion comprises a first block and a second block, and a groove defined between the first block and the second block and opens towards the second molding die.

13. The molding device as claimed in claim 12, wherein a cross section of the groove is shaped as a trapezoid.

14. The molding device as claimed in claim 12, wherein the entrance is defined between the first block and the second molding die and configured between the first runners and the receiving cavity, the receiving cavity is defined between the groove and the second molding die, and the exit is defined between the second block and the second molding die and communicates with the receiving cavity and the molding cavity.

15. The molding device as claimed in claim 10, wherein a height of the entrance is substantially equal to that of the exit, and is less than that of the receiving cavity.

16. The molding device as claimed in claim 12, wherein the second molding die defines a plurality of cylinders to receive a plurality of pistons, each of the plurality of first runners communicates with the corresponding cylinder and extends from the corresponding cylinder towards the first block, each of the plurality of pistons is compressed to force the molding compound passing through the corresponding cylinders to fill into the molding cavity.

17. The molding device as claimed in claim 16, wherein the second molding die further defines a recess portion communicating with the molding cavity and opening towards the first molding die, the substrate is received in the recess portion and comprises a degating region structured on one side of the substrate and contiguous with the protruding portion.

18. The molding device as claimed in claim 17, wherein the degating region comprises a first layer and a second layer, the first layer is made of copper and the second layer is selectively made of cuprum oxide and organic protective film.

19. The molding device as claimed in claim 17, wherein the degating region is structured as monolayer and made of copper, aurum or gold-nickel alloy.

20. A molding device to encapsulate a substrate configured with a plurality of electronic elements comprising a first molding die and a second molding die opposite with each other and collectively forming a molding cavity to receive the substrate, a cylinder accompanied with a piston configured to fill molding compound to the molding cavity by way of a runner, a protruding portion protruding from one of the first molding die and the second molding die to narrow a path of the molding compound to the molding cavity in the runner, so as to lower a speed of the molding compound flowing to the molding cavity to fully encapsulate the electronic elements on the substrate.
